(19) United States
(12) Patent Application Publication
(10) Pub. No.: US 2007/0158178 A1
(43) Pub. Date: Jul. 12, 2007

(54) Method and apparatus for deposition of low-k dielectric materials

(75) Inventor: Alexander Leybovich, Hilliard, OH (US)

Correspondence Address: WEGMAN, HESSLER & VANDERBURG, 6055 ROCKSIDE WOODS BOULEVARD, SUITE 200, CLEVELAND, OH, 44131, US

(73) Assignee: Tosoh SMD, Inc., Grove City, OH (US)

(21) Appl. No.: 10/624,384

(22) Filed: Jul. 22, 2003

Related U.S. Application Data
(60) Provisional application No. 60/397,803, filed on Jul. 23, 2002.

(51) Int. Cl. C23C 14/32; C23C 14/00

(52) U.S. Cl. 204/192.1; 204/298.02

(57) ABSTRACT

A system and method for physical vapor deposition (PVD) of dielectric material characterized by the conversion of a beam of positively charged ions into a beam of neutral particles, said beam of neutral particles being directed to bombard a sputtering target. In operation, sputtering targets comprised of low-k dielectric material can be successfully sputtered by such a beam of neutral particles, allowing for the integration of low-k dielectric materials into the on-chip wiring of semiconductor devices.

### CROSS-REFERENCE TO RELATED APPLICATION

This application claims the benefit of U.S. Provisional Patent Application Ser. No. 60/397,803 filed Jul. 23, 2002.

### BACKGROUND OF THE INVENTION

1. Field of the Invention

This invention relates to a method and system, and more particularly relates to a physical vapor deposition (PVD) method and system intended for deposition of dielectric materials, including low dielectric constant (low-k) materials, onto substrates during the fabrication of integrated circuits and other electronic, opto-electronic, microwave, and micro electromechanical (MEM) devices.

2. Background of the Related Arts

In the fabrication of integrated circuits and other electronic, opto-electronic, microwave, and MEM devices on substrates, multiple deposition and etch processes are performed in sequence to fabricate the desired electronic structures or devices. The current trend in fabrication has been to improve the performance and reliability of devices with simultaneous reduction in the manufacturing cost. Improved performance and reduced manufacturing costs can be achieved by reducing the overall size of the features composing these devices and by increasing the device density on a single die. The ultimate goal is to fabricate devices in such a way that combines improved performance (speed and capacity), with improved cost efficiency of manufacturing process. For these and many other reasons semiconductor material processing continues to attract close attention of researchers.

One area of intensive research includes the search for low dielectric constant (low-k) materials suitable for semiconductor applications. Low-k dielectrics are used as insulating material for on-chip interconnects, to reduce capacitive coupling between wires. The major benefit of using low-k dielectrics as an insulating material for on-chip interconnects is to reduce the capacitive coupling or “cross-talk” between on-chip components. Moreover, reducing the capacitive value (k) of the insulating layer, in combination with the utilization of low-resistivity copper thin film wires, provides a significant reduction in the time constant (RC) of the device, thereby boosting device performance. Materials such as fluorsilicate glasses FSG, organosilicate glasses OSG, porous oxides with carbon component, porous silica, polyaromatic polymers and others are currently under evaluation for low-k applications. The k values for the above materials are typically in the 1.3 to 3.7 range.

While these dielectric materials are evaluated, the search for methods of their processing gains a main focus. Among the methods known for film deposition, only two techniques have attracted the main attention for deposition of low-k materials. The first technique is chemical vapor deposition (CVD) or plasma enhanced chemical vapor deposition (PECVD). This technique is preferably used to deposit organosilicate glasses. The other technique is the spin-on method, which is the preferred method for depositing polymer materials. Each technique has its own advantages and disadvantages. The CVD deposited films usually exhibit good thermal stability, they are reasonably hard, but they can be fragile. On the other hand, spin-on organic dielectric films have reasonable thermal stability, they are tough, but they are soft. Lowering the k value of these materials also tends to reduce the niaterial's ability to adhere to other films. As such, low-k dielectric materials have mechanical stability concerns which further complicates the chip manufacturing and packaging process.

In addition to such mechanical stability concerns, low-k dielectrics present serious integration challenges for chip manufacturers. Low-k dielectrics often require separate barrier layers, such as embedded etch stop layers, hard masks and CMP stops. Moreover, low-k dielectric materials require a carefully tailored etching process, which is not readily incorporated into the standard Si-based technology with copper interconnects. Therefore, implementation of low-k material into circuit chip design remains relatively limited and requires extremely careful circuit and process design.

Traditionally, cathodic sputtering is widely used for the deposition of thin layers of material onto desired substrates. Basically, this process requires a gas ion bombardment of the target having a face formed of a desired material that is to be deposited as a thin film or layer on a substrate. Ion bombardment of the target not only causes atoms or molecules of the target material to be sputtered, but imparts considerable thermal energy to the target. Such thermal heating of the target material is particularly troublesome for the deposition of low-k dielectric, especially organic, materials since such materials tend to be more susceptible to thermal or thermo-chemical destruction under excessive heating conditions.

In cathodic sputtering, the sputtering target typically forms a part of a cathode assembly which together with an anode is placed in an evacuated chamber that contains an inert gas. A high voltage electrical field is applied across the cathode and anode. The inert gas is ionized by collision with the electrons ejected from the cathode. Positively charged gas ions are attracted to the cathode and, upon impingement with the target surface, dislodge the target material. The dislodged target materials traverse the evacuated enclosure along a transport region and deposit as a thin film on the desired substrate that is normally located proximate the anode.

In addition to the use of an electric field, increasing sputtering rates have been achieved by the concurrent use of a magnetic field that is superimposed over the electrical field over the surface of the target. Such methods are well known to impart considerable thermal energy to the target. Consequently, these methods, in addition to requiring costly and labor intensive means to electrically bias the target plate, require costly and labor intensive cooling devices to carry away the heat generated by the ion bombardment of the target.

Accordingly, it would be desirable to have a method and apparatus capable of providing high sputtering yields without the negative consequence of imparting excessive thermal energy to the target. Moroever, there is a continuing need to reduce the time constant or RC delay in on-chip wiring through the development of low-k dielectrics and technology. Not only do the materials themselves need to be optimized, but also the process steps around them. Therefore, it is an object of the present invention to provide the means for more seamless integration of low-k materials into the on-chip wiring of semiconductor devices.

### SUMMARY OF THE INVENTION

The present invention provides a method and an apparatus for the deposition of dielectric materials using the process of PVD. In one aspect of the invention a method for the deposition of dielectric, preferably low-k, materials is provided. The method includes the step of forming a low energy, large aperture, energy-monochromatic ion beam, preferably from non-active atomic or molecular gas. The method also includes the step of converting said energy-monochromatic ion beam into an energy-monochromatic beam of neutrals, directed towards a sputtering target. The method also includes the step of exposing said target to bombardment by said beam of neutrals, thereby causing said target to sputter. Said target preferably made of low-k dielectric, possibly inorganic or organic material. The above method also includes the step of formation of a cloud of thermalized sputtered particles, emitted from the target, and directed towards a substrate. Finally, the method includes the step of depositing said sputtered particles onto said substrate.

In another aspect of the invention, a processing apparatus for the deposition of dielectric material is provided. The processing apparatus basically comprises a sputtering target, such target possibly comprising inorganic or organic low-k dielectric material; a low energy, large aperture source for the formation of an energy-monochromatic ion beam; charge transfer means to perform ion beam neutralization; means for confining and directing a beam of neutral particles towards the sputtering target; and means for directing a cloud of thermalized sputtered particles of dielectric material towards a substrate for deposition.

### BRIEF DESCRIPTION OF THE DRAWINGS

FIG. 1 is a general schematic diagram of a type of apparatus in which ion charge neutralization occurs inside a charge transfer chamber;

FIG. 2 is a general schematic diagram of an alternative type of apparatus for glancing angle sputtering of a conical target;

FIG. 2A is a more detailed schematic view of the source of neutrals chamber in FIG. 2; and

FIG. 3 is a general flow diagram summarizing the new and original steps for depositing dielectric materials onto a substrate.

### DETAILED DESCRIPTION OF THE PREFERRED EMBODIMENT

As best shown in FIG. 1, the method and apparatus of the present invention comprises an ionization source chamber 1 and an ion extracting system 2 which provide means, preferably by way of DC excitation of plasma, whereby a low energy (preferably in the range of 100-400 eV), large aperture (preferably 10 cm in diameter), energy-monochromatic (uniform energy level), positively charged (ionic), relatively fast moving ion beam may be formed, preferably from non-active atomic or molecular gas, as is well-known and customary in the art. Said extracting system 2 provides optics means, preferably by way of an applied electric field, to equalize, shape, focus, and direct individual positively charged ions of said fast moving positively charged ion beam into a charge transfer chamber 3 containing a volume of relatively slow moving neutrally charged gas atoms or molecules. Said volume of relatively slow moving neutrally charged gas atoms or molecules contained inside charge transfer chamber 3 provide charge transfer means for converting said positively charged ion beam into an energy-monochromatic beam of neutrals 28 by way of an ion neutralization process founded on the principle of charge transfer phenomenon. Such charge transfer phenomenon is shown to occur when said relatively fast moving positively charged ions, having been directed into said charge transfer chamber 3, collide with said volume of relatively slow moving neutral gas atoms or molecules contained inside said charge transfer chamber 3. During these inelastic collision events, said fast moving positively charged ions acquire an electron from said slow moving neutral gas atoms or molecules, said fast moving positively charged ions being converted into fast moving neutral particles, having retained almost all of their pre-collision energy and momentum. Said fast moving neutral particles continue to propagate along their original path, forming a beam of neutrals 28 directed towards a sputtering target 5 as best shown in FIG. 1. It follows that the new and original method of the present invention includes the step of exposing said target 5 to said beam of neutrals 28, thereby causing said target 5 to sputter particles 30 as best shown in FIG. 1.

Referring again to FIG. 1, the method of the present invention also includes the step of formation of a cloud 6 of sputtered material directed toward a substrate 7 for deposition. A gradual increase in the density of cloud 6 as best shown in FIG. 1 is achieved by a thermalization process whereby gas pressure in the sputtering chamber transport region is maintained at a higher level compared to conventional PVD. Such higher gas pressure increases the number of collisions between gas molecules and said sputtered particles 30 which in turn decreases the directional momentum of said sputtered particles 30 as they propagate along the transport region toward said substrate 7. Such decrease in directional momentum, being proportional to distance traveled, tends to increase the density of said cloud 6 of said sputtered particles proximate the substrate 7 as best shown in FIG. 1. In operation, the relatively high density cloud 6 of sputtered particles proximate the substrate 7 increases the probability that said sputtered particles will become deposited onto the substrate, thereby improving the trench and via coverage on said substrate 7. Moreover, the thermalization process provides means of maintaining the energy of said cloud of said sputtered particles 30 high enough to improve the adhesion of said sputtered particles 30 onto said substrate 7 relative to the adhesion characteristics achieved under normal CVD or spin-on techniques.

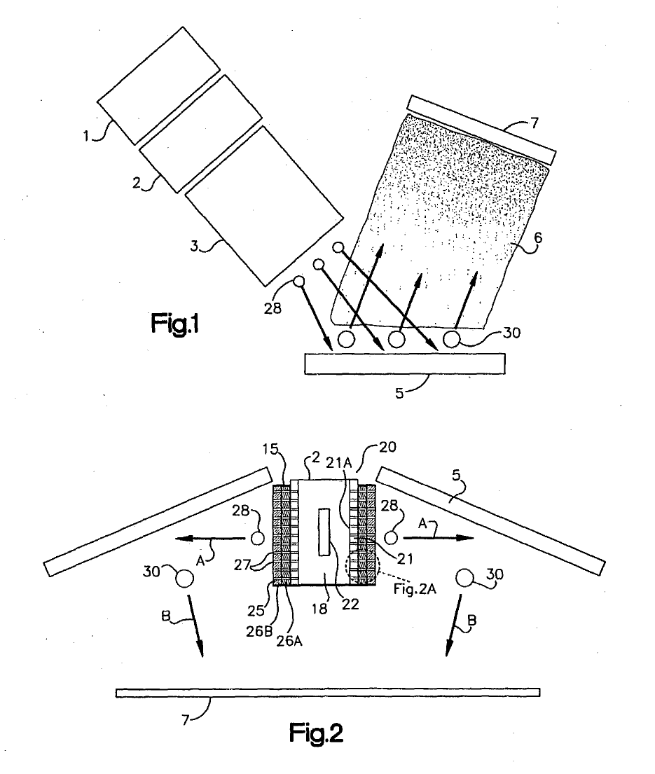

A preferred alternative embodiment of the present invention is best shown in FIG. 2. Referring to FIG. 2, a sputtering source mounting fixture (not shown) operates to mount a source of neutrals 15 by protruding it through a hole 20 in the apex area of a target 5. Such alternative embodiment of the present invention can be used with either a conical shaped target 5, as shown in FIG. 2, or with hollow cathode targets (not shown) by placing the source of neutrals 15 inside the target inner space through said hole 20 formed in the target apex with the apex angle preferably in the range of 100°-200° as best shown in FIG. 2. The source of neutrals 15 with cylindrical extracting system 2 is formed by a cold cathode-emitter 18 designed as a hollow cathode 21 with inner anode 22. Similar devices with the cold cathode-emitter 18 for providing a source of neutrals 15 are available from Anatech Limited, Springfield, Va. 22151. In the present embodiment, the cathode emitting surface 21A is surrounded by a set of coaxial cylindrical grids 26A and 26B comprising an ion optics chamber 25. Said grids 26A and 26B have a series of coaxial holes 27 arranged in a pattern of M rows with N equally spaced holes per row. Plasma inside the cold cathode-emitter 18 of the source of neutrals 15 is formed by DC excitation. No thermionic tips or filaments are used. In operation, positively charged ions (not shown) are extracted from the cathode emitting surface 21A and directed into the grid incapsulated region of the source of neutrals 15 wherein said positively charged ions are neutralized by way of the aforesaid charge transfer phenomenon during their passage through said holes 27 of grids 26A and 26B as is well known and customary in the art. A relatively high percentage of said positively charged ions are ultimately neutralized while passing through the grid system. As such, almost all of the species leaving the source will have been converted to energetic neutrals 28. If the backfill gas inside the source of neutrals 15 is argon, then the neutralized species leaving the source of neutrals 15 are argon atoms. Neutrals 28 leaving the source of neutrals 15 create a corona-like beam advancing toward the target surface 5 at a glancing angle as shown by arrow A in FIG. 2. At such an angle of bombardment, sputtered particles 30 will leave the target surface at a proportional glancing angle as shown by arrow B in FIG. 2. Such glancing angle bombardment and angular emission prevents, or at least minimizes, the interception of sputtered particles by the walls of the source of neutrals 15 while the sputtered particles 30 are directed toward substrate 7. Another advantage of such glancing angle sputtering is the increased sputtering yield that allows one to use a lower density flux of neutrals to achieve a reasonable sputter rate and, at the same time, to reduce the temperature of the sputter target surface, making it possible to sputter organic materials.

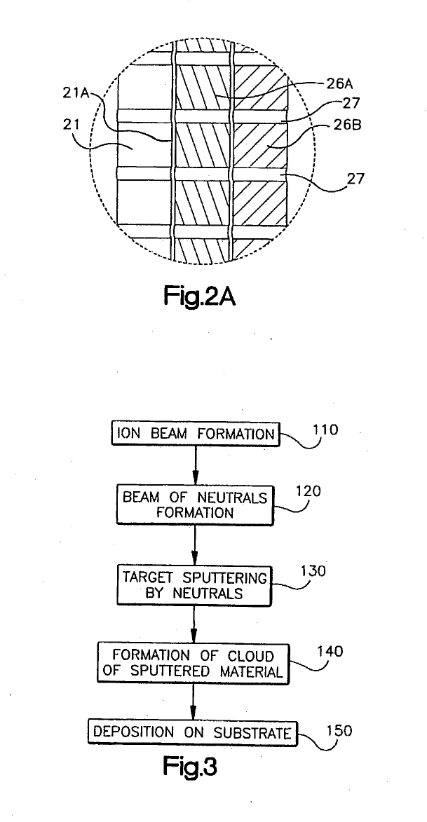

The steps comprising the method of the present invention may be summarized as shown in FIG. 3. The first step of ion beam formation 110, followed by the step of formation of a beam of neutrals 120, then the step of target sputtering by said beam of neutrals 130, then the step of formation of a cloud of sputtered material 140, and finally the step of deposition of said sputtered material onto a substrate 150.

Referring again to the aforesaid charge transfer phenomenon, studies have shown that if the charge transfer conditions have been chosen properly, it is practically possible to convert almost all of the positively charged ions of the original ion beam into a beam of relatively fast moving neutrals. Furthermore, it was shown that if, for example, 90% of ions of the original ion beam are converted into neutral particles, then the beam of those neutrals would retain almost 85% of the momentum of the original ion beam. The ability to retain momentum and energy by the beam of neutrals is of practical importance since it opens the opportunity for practical implementation of this phenomenon in the present invention. Studies have shown that organic glasses, polyamides and other organic (i.e., low-k) materials can be successfully sputtered by the beam of fast neutrals.

The foregoing has described a new and original PVD system that provides a significant improvement in PVD of dielectric materials. Due to the ion neutralization process described herein, the method of the present invention provides advantage over conventional PVD because the present invention does not require target surface charge compensation. Conventional PVD systems require target surface charge compensation in order to provide continuous sputtering of dielectric materials as is well known in the art. Such target surface charge compensation is typically perfomed by electrons that have been extracted from the plasma of RF discharge, or provided by an external source. As such, the additional electron bombardment of the target surface significantly raises the target surface temperature and may result in thermal or thermo-chemical destruction of the target material. For this reason, organic based materials could not be sputtered by conventional RF sputtering.

The foregoing has also described a preferred alternative embodiment of the present invention whereby increased sputtering yields may be achieved by way of glancing angle sputtering as best shown in FIG. 2. Studies have shown that directing a beam of relatively heavy particles such as ions or neutrals towards the target surface at a glancing angle tends to increase the sputtering yield of target particles due to collision displacement cascades near the target surface. Such collision displacement cascades near the target surface increases the probability that such target particles will be ultimately emitted from the target, thereby increasing the sputtering yield. It is important to note that such increased sputtering yields are advantageous, especially where low-k dielectric materials are used, because a lower density of bombarding beams may be used to generate equivalent sputtering rates, thereby reducing the thermal energy imparted to the target.

The method according to the present invention also provides an evident improvement when compared with reactive PVD methods. In contrast to such reactive PVD methods, virtually any dielectric material may be sputtered successfully and ultimately deposited using the method of the present invention. Moreover, the method according to the present invention provides an important improvement when compared with PECVD since the present invention, in contrast to PECVD, does not require reactive gases to deposit the film. The method according to the present invention also provides an improvement when compared with the aforementioned spin-on technique due to the improved adhesion and mechanical properties of the dielectric material achieved by the method of the present invention.

While specific embodiments of the present invention have been described, it will be apparent to those skilled in the art that various modifications thereto can be made without departing from the spirit and scope of the invention as defined in the following claims.

What is claimed is:

1. A method for the physical vapor deposition (PVD) of dielectric material onto a substrate, said method comprising:
(a) forming an energized monochromatic ion beam;
(b) converting said ion beam into an energized monochromatic beam of neutrals by passing the ion beam through a charge transfer chamber containing a volume of neutrally charged gas atoms or molecules, wherein the neutrally charged gas atoms or molecules are slower moving relative to said ion beam, such that said relatively fast moving positively charged ions collide with said relatively slow moving neutral gas atoms or molecules inside said charge transfer chamber such that said collision events cause said positively charged ions to acquire an electron from said slow moving neutral gas atoms or molecules;
(c) directing said beam of neutrals toward a sputtering target;
(d) exposing said target to bombardment by said beam of neutrals;
(e) sputtering particles from said target;
(f) forming a cloud of said sputtered particles proximate to a substrate, wherein the cloud is formed by an increased density of thermalized particles; and
(g) depositing said sputtered particles onto said substrate.

2. The method as recited in claim 1 wherein said target comprises low-k dielectric material.

3. The method as recited in claim 2 wherein said low-k dielectric material is organic.

4. The method as recited in claim 2 wherein said low-k dielectric material is inorganic.

5. The method as recited in claim 1 wherein said low-k dielectric material has a dielectric constant of about 1.3 to 3.7.

6. A system for the physical vapor deposition (PVD) of dielectric material onto a substrate, said system comprising:
(a) a sputtering target;
(b) a low energy, large aperture ion source of energized monochromatic ions;
(c) an ion optics system for equalizing, shaping, and directing said ions into an ion beam;
(d) a charge transfer system for neutralization of said ion beam into a beam of neutrals comprising a charge transfer chamber having a volume of slower moving neutrally charged gas atoms or molecules, wherein as the ion beam passes through the charge transfer chamber, said relatively fast moving positively charged ions collide with said relatively slow moving neutral gas atoms or molecules such that during said collision events said fast moving positively charged ions acquire an electron from said slow moving neutral gas atoms or molecules;
(e) means for directing said beam of neutrals toward the target, said beam of neutrals bombarding said target and causing said target to emit sputtered particles;
(f) means for forming a thermalized cloud of said sputtered particles proximate said substrate; and
(g) means for depositing said cloud of said sputtered particles onto said substrate.

7. The system as recited in claim 6, wherein said target comprises low-k dielectric material.

8. The system as recited in claim 7 wherein said low-k dielectric material is organic.

9. The system as recited in claim 7 wherein said low-k dielectric material is inorganic.

10. The method as recited in claim 1 wherein the ion beam is converted into an energized monochromatic beam of neutrals by passing the ion beam through a charge transfer chamber containing a volume of slower moving neutrally charged gas atoms or molecules, wherein the neutrally charged gas atoms or molecules are slower moving relative to said ion beam.

11. The method as recited in claim 10 wherein the energized monochromatic ion beam is formed having an ion energy in the range of 100-400 eV.

12. The method as recited in claim 1 wherein the energized ion beam is converted into the energized monochromatic beam of neutrals by directing said ion beam through a charge transfer chamber containing a volume of relatively slower moving neutrally charged Ar gas.

13. canceled

14. The method as recited in claim 1 wherein the cloud is formed by increasing the number of collisions between gas molecules and sputtered particles to decrease the directional momentum of said sputtered particles as they propagate toward the substrate.

15. A method for the physical vapor deposition (PVD) of dielectric material onto a substrate, said method comprising:
forming an energized monochromatic ion beam;
converting said ion beam into an energized monochromatic beam of neutrals by directing said ion beam through a charge transfer chamber containing a volume of relatively slower moving neutrally charged Ar gas molecules, wherein the neutrally charged Ar gas molecules are slower moving relative to said ion beam such that said relatively fast moving positively charged ions collide with said relatively slow moving neutral Ar gas molecules contained inside said charge transfer chamber so that during said collision events, said fast moving positively charged ions acquire an electron from said slow moving Ar gas molecules;
directing said beam of neutrals toward a sputtering target;
exposing said target to bombardment by said beam of neutrals;
sputtering particles from said target;
forming a cloud of thermalized sputtered particles proximate to a substrate, wherein the cloud is formed by increasing the number of collisions between gas molecules and sputtered particles to decrease the directional momentum of said sputtered particles as they propagate toward the substrate; and
depositing said sputtered particles onto said substrate.

16. The method as recited in claim 15 wherein the energized monochromatic ion beam is formed having an ion energy in the range of 100-400 eV.

17. The method as recited in claim 15 wherein said target comprises a material selected from the group consisting of fluorsilicate glasses (FSG), organosilicate glasses (OSG), porous oxides with carbon component, porous silica, and polyaromatic polymers.

18. The method as recited in claim 15 wherein during the step of exposing said target to bombardment by said beam of neutrals, the surface of the target is free of target surface charge compensation.

19. The method as recited in claim 1 wherein during the step of exposing said target to bombardment by said beam of neutrals, the surface of the target is free of target surface charge compensation.

20. The system as recited in claim 6, wherein means for directing the beam of neutrals directs the beam toward a target having a surface free of target surface charge compensation.
